(19) United States
(12) Patent Application Publication
(10) Pub. No.: US 2025/0087611 A1
(43) Pub. Date: Mar. 13, 2025

(54) INTEGRATED DEVICE COMPRISING A PILLAR SHELL INTERCONNECT AND AN INNER SOLDER INTERCONNECT

(71) Applicant: QUALCOMM Incorporated, San Diego, CA (US)

(72) Inventors: Yujen CHEN, Taichung (TW); Yangyang SUN, San Diego, CA (US); Wei WANG, San Diego, CA (US)

(21) Appl. No.: 18/465,717

(22) Filed: Sep. 12, 2023

(51) Int. Cl. H01L 23/00

(52) U.S. Cl. CPC H01L 24/13; H01L 24/03; H01L 24/04; H01L 24/05; H01L 24/11; H01L 24/16; H01L 24/81; H01L 2224/0345; H01L 2224/03912; H01L 2224/0401; H01L 2224/05022; H01L 2224/05073; H01L 2224/05558; H01L 2224/05564; H01L 2224/05573; H01L 2224/1146; H01L 2224/11849; H01L 2224/13014; H01L 2224/13083; H01L 2224/13147; H01L 2224/16227; H01L 2224/81815

(57) ABSTRACT

An integrated device comprising a die substrate; a plurality of pads; a plurality of inner solder interconnects coupled to the plurality of pads; and a plurality of pillar shell interconnects coupled to the plurality of inner solder interconnects. The plurality of inner solder interconnects are located between the plurality of pillar shell interconnects and the plurality of pads.

### FIELD

Various features relate to integrated devices.

### BACKGROUND

A package may include a substrate and integrated devices. These components are coupled together to provide a package that may perform various electrical functions. The performance of a package and its components may depend on the quality of the joints between various components of the package. There is an ongoing need to provide packages that include secure and reliable joints between components.

### SUMMARY

Various features relate to integrated devices.

An integrated device comprising a die substrate; a plurality of pads; a plurality of inner solder interconnects coupled to the plurality of pads; and a plurality of pillar shell interconnects coupled to the plurality of inner solder interconnects. The plurality of inner solder interconnects are located between the plurality of pillar shell interconnects and the plurality of pads.

Another example provides a package comprising a substrate; and an integrated device coupled to the substrate through a plurality of solder interconnects. The integrated device comprises a die substrate; a plurality of pads; a plurality of inner solder interconnects coupled to the plurality of pads; and a plurality of pillar shell interconnects coupled to the plurality of inner solder interconnects. The plurality of inner solder interconnects are located between the plurality of pillar shell interconnects and the plurality of pads. The plurality of solder interconnects are coupled to the plurality of pillar shell interconnects.

Another example provides a method for fabricating an integrated device. The method provides an integrated device comprising a die substrate and a plurality of pads. The method couples a plurality of inner solder interconnects to the plurality of pads. The method forms a plurality of pillar shell interconnects that are coupled to the plurality of inner solder interconnects such that the plurality of inner solder interconnects are located between the plurality of pillar shell interconnects and the plurality of pads.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device that includes pillar shell interconnects and inner solder interconnects.

FIG. 2 illustrates an exemplary a pillar shell interconnect and an inner solder interconnect.

FIG. 3 illustrates a cross sectional plan view of an exemplary pillar shell interconnect and an inner solder interconnect.

FIG. 4 illustrates a cross sectional profile view of an exemplary package comprising an integrated device that includes pillar shell interconnects and inner solder interconnects.

FIG. 5 illustrates a close-up view of an exemplary package comprising an integrated device that includes pillar shell interconnects and inner solder interconnects, where the integrated device is coupled to a substrate.

FIGS. 6A-6G illustrate an exemplary sequence for fabricating an integrated device that includes pillar shell interconnects and inner solder interconnects.

FIG. 7 illustrates an exemplary flow diagram of a method for fabricating an integrated device that includes pillar shell interconnects and inner solder interconnects.

FIG. 8 illustrate an exemplary sequence for fabricating a package comprising an integrated device that includes pillar shell interconnects and inner solder interconnects.

FIG. 9 illustrates an exemplary flow diagram of a method for fabricating a package comprising an integrated device that includes pillar shell interconnects and inner solder interconnects.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. The present disclosure describes a package that includes a substrate and an integrated device coupled to the substrate through a plurality of solder interconnects. The integrated device includes a die substrate, a plurality of pads, a plurality of inner solder interconnects coupled to the plurality of pads, and a plurality of pillar shell interconnects coupled to the plurality of inner solder interconnects. The plurality of inner solder interconnects are located between the plurality of pillar shell interconnects and the plurality of pads. The plurality of solder interconnects are coupled to the plurality of pillar shell interconnects. The integrated device may include a plurality of underbump metallization interconnects. The plurality of inner solder interconnects may be coupled to the plurality of pads through the plurality of underbump metallization interconnects. The use of the plurality of inner solder interconnects provide a material that is better at absorbing stress during the coupling of the integrated device to the substrate, which may help reduce stress that is transferred to the dielectric layers of the integrated device. Less stress on the dielectric layers of an integrated device, means a less likelihood of delamination of the dielectric layers, which can result in a more robust and reliable joint between the integrated device and the substrate. A more robust and reliable joint provides a more reliable electrical path for current and/or signal traveling between the integrated device and the substrate, which can lead to improved performances for the integrated device and the package.

### Exemplary Integrated Device Comprising a Pillar Shell Interconnect an Inner Solder Interconnect

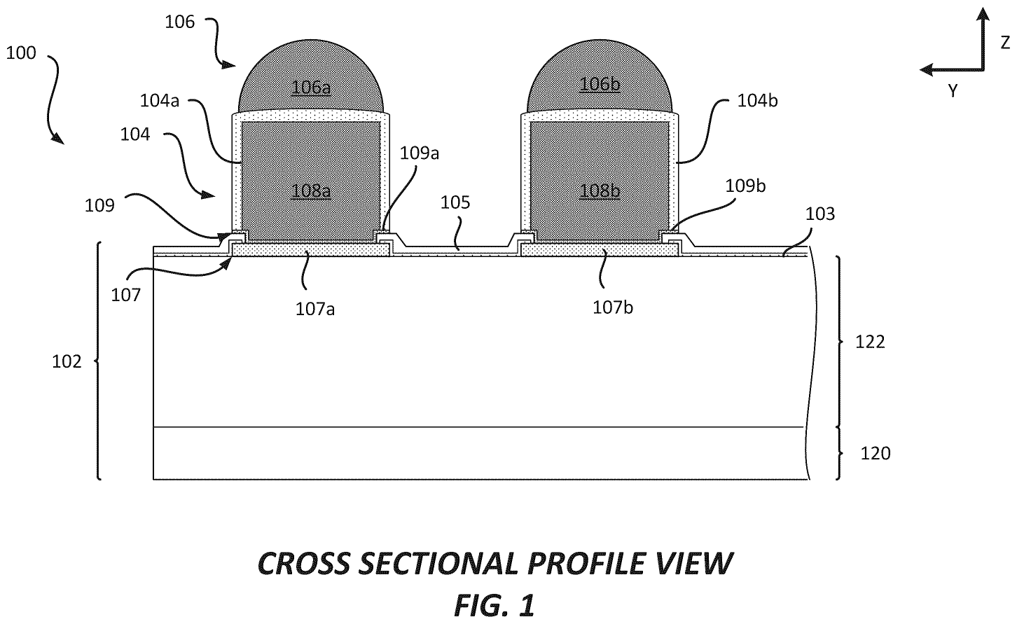

FIG. 1 illustrates a cross sectional profile view of an integrated device 100 that includes pillar shell interconnects and an inner solder interconnect. The integrated device 100 includes a die portion 102, a plurality of pillar shell interconnects 104, a plurality of solder interconnects 106 and a plurality of inner solder interconnects 108. The integrated device 100 may include a flip chip. As will be further described below, a pillar shell interconnect is different from a block pillar, in that the pillar shell includes a hollow portion that is at least partially occupied by another material, such as solder. A pillar, a pillar shell and/or a pillar interconnect may include copper.

The die portion 102 includes a die substrate 120, an interconnection portion 122, a passivation layer 103 (e.g., first passivation layer), a passivation layer 105 (e.g., second passivation layer), a plurality of pads 107. The integrated device 100 may also include a plurality of underbump metallization interconnects 109. The die substrate 120 may include silicon (Si). A plurality of cells and/or transistors (not shown) may be formed in and/or over the die substrate 120. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 120. The interconnection portion 122 is located over and coupled to the die substrate 120. The interconnection portion 122 may be a die interconnection portion. The interconnection portion 122 may be configured to be electrically coupled to the plurality of cells and/or transistors located in and/or over the die substrate 120. The interconnection portion 122 may include at least one dielectric layer (e.g., die dielectric layer) and a plurality of die interconnects (not shown), where the plurality of die interconnects are coupled to the plurality of cells and/or transistors. In some implementations, a back end of line (BEOL) process may be used to fabricate the interconnection portion 122.

The passivation layer 103 is located over and coupled to the interconnection portion 122. The passivation layer 105 is located over and coupled to the passivation layer 103. The passivation layer 105 may include a different material from the passivation layer 103. In some implementations, the passivation layer 103 and the passivation layer 105 may be considered as one passivation layer. In some implementations, there may be one passivation layer or more than two passivation layers. The plurality of pads 107 is located over the interconnection portion 122. The plurality of pads 107 may be coupled to die interconnects of the interconnection portion 122. The plurality of underbump metallization interconnects 109 may be coupled to the plurality of pads 107. In some implementations, the passivation layer 103, the passivation layer 105, the plurality of pads 107 and/or the plurality of underbump metallization interconnects 109 may be considered part of the interconnection portion 122. In some implementations, a back end of line (BEOL) process may be used to fabricate the passivation layer 103, the passivation layer 105, the plurality of pads 107 and/or the plurality of underbump metallization interconnects 109.

The plurality of inner solder interconnects 108 are coupled (e.g., directly or indirectly) to the plurality of pads 107. The plurality of inner solder interconnects 108 may be coupled to the plurality of pads 107 through at least the plurality of underbump metallization interconnects 109. In some implementations, the plurality of inner solder interconnects 108 may be coupled to the plurality of pads 107 through at least a plurality of metallization interconnects (e.g., redistribution interconnects) and the plurality of underbump metallization interconnects 109. The plurality of pillar shell interconnects 104 are coupled to the plurality of inner solder interconnects 108. The plurality of inner solder interconnects 108 may be located between (e.g., located vertically between) the plurality of pads 107 and the plurality of pillar shell interconnects 104. The plurality of inner solder interconnects 108 may be located between (e.g., located vertically between) the plurality of underbump metallization interconnects 109 and the plurality of pillar shell interconnects 104. The plurality of solder interconnects 106 may be coupled to the plurality of pillar shell interconnects 104. The plurality of solder interconnects 106 may be separate from the plurality of inner solder interconnects 108. For example, the plurality of solder interconnects 106 may be separate from the plurality of inner solder interconnects 108 when the plurality of solder interconnects 106 are not directly touching the plurality of inner solder interconnects 108. The plurality of inner solder interconnects 108 are touching the plurality of underbump metallization interconnects 109 and the plurality of pillar shell interconnects 104. In some implementations, at least one pillar shell interconnect from the plurality of pillar shell interconnects 104 may include a first material, and at least one inner solder interconnect from the plurality of inner solder interconnects 108 includes a second material that is different from the first material. For example, a pillar shell interconnect may include copper (e.g., first material), and an inner solder interconnect may include solder (e.g., second material).

The plurality of pillar shell interconnects 104 include a first pillar shell interconnect 104a and a second pillar shell interconnect 104b. The plurality of solder interconnects 106 include a first solder interconnect 106a and a second solder interconnect 106b. The plurality of pads 107 include a first pad 107a and a second pad 107b. The plurality of inner solder interconnects 108 include a first inner solder interconnect 108a and a second inner solder interconnect 108b. The plurality of underbump metallization interconnects 109 include a first underbump metallization interconnect 109a and a second underbump metallization interconnect 109b.

The first inner solder interconnect 108a is coupled to the first underbump metallization interconnect 109a and the first pillar shell interconnect 104a. The first solder interconnect 106a is coupled to the first pillar shell interconnect 104a. The first pillar shell interconnect 104a includes a first lateral portion and a first top portion. The first top portion includes a first inner top surface and a first outer top surface. The first lateral portion may include a first inner lateral surface and a first outer lateral surface. The first inner solder interconnect 108a may be touching the first underbump metallization interconnect 109a, the first inner lateral inner surface of the lateral portion of the first pillar shell interconnect 104a and the first inner top surface of the first top portion of the first pillar shell interconnect 104a. The first pillar shell interconnect 104a may be touching the first underbump metallization interconnect 109a, the passivation layer 103 and/or the passivation layer 105. The first solder interconnect 106a may touch the first outer top surface of the first top portion of the first pillar shell interconnect 104a. In some implementations, the first inner solder interconnect 108a may touch the first underbump metallization interconnect 109a and/or the first pad 107a. In some implementations, the first underbump metallization interconnect 109a may be considered part of the first pad 107a. In such instances, when the first inner solder interconnect 108a touches the first underbump metallization interconnect 109a, the first inner solder interconnect 108a may be considered to be touching the first pad 107a. Additionally, in at least some implementations, when the first inner solder interconnect 108a is coupled to the first pad 107a, it may mean that the first inner solder interconnect 108a is directly coupled to the first pad 107a or indirectly coupled to the first pad 107a through at least the first underbump metallization interconnect 109a.

The second inner solder interconnect 108b is coupled to the second underbump metallization interconnect 109b and the second pillar shell interconnect 104b. The second solder interconnect 106b is coupled to the second pillar shell interconnect 104b. The second pillar shell interconnect 104b includes a second lateral portion and a second top portion. The second top portion includes a second inner top surface and a second outer top surface. The second lateral portion may include a second inner lateral surface and a second outer lateral surface. The second inner solder interconnect 108b may be touching the second underbump metallization interconnect 109b, the second inner lateral surface of the lateral portion of the second pillar shell interconnect 104b and the second inner top surface of the second top portion of the second pillar shell interconnect 104b. The second pillar shell interconnect 104b may be touching the second underbump metallization interconnect 109b, the passivation layer 103 and/or the passivation layer 105. The second solder interconnect 106b may touch the second outer top surface of the second top portion of the second pillar shell interconnect 104b. In some implementations, the second inner solder interconnect 108b may touch the second underbump metallization interconnect 109b and/or the second pad 107b. In some implementations, the second underbump metallization interconnect 109b may be considered part of the second pad 107b. In such instances, when the second inner solder interconnect 108b touches the second underbump metallization interconnect 109b, the second inner solder interconnect 108b may considered to be touching the second pad 107b. Additionally, in at least some implementations, when the second inner solder interconnect 108b is coupled to the second pad 107b, it may mean that the second inner solder interconnect 108b is directly coupled to the second pad 107b or indirectly coupled to the second pad 107b through at least the second underbump metallization interconnect 109b.

As mentioned above, a pillar shell interconnect and/or a pillar interconnect may include copper, which has a higher Young's modulus than that of solder. Young's modulus describes clastic characteristics of a material. The solder's lower Young's modulus relative to copper, means that solder is more effective at absorbing stress relative to copper. Moreover, solder may also include creep deformation characteristics, which may also help in absorbing stress. Thus, the use of the plurality of inner solder interconnects 108 provides a material that is better at absorbing stress during the coupling of the integrated device 100 to a substrate, which may help reduce stress that is transferred to the dielectric layers of the integrated device 100. Less stress on the dielectric layers of the integrated device may mean a less likelihood of delamination of the dielectric layers, which can result in a more robust and reliable joint between the integrated device 100 and a substrate (e.g., package substrate). A more robust and reliable joint provides a more reliable electrical path for current and/or signal traveling between the integrated device 100 and a substrate, which can lead to improved performances for the integrated device and the package. It should be noted that the material listed above are exemplary. Other implementations may use of materials, other types of materials and/or other combinations of materials.

In some implementations, there may be additional interconnects between the plurality of pads 107, the plurality of underbump metallization interconnects 109 and the plurality of inner solder interconnects 108. In some implementations, there may be additional interconnects between (i) the plurality of pads 107 and/or the plurality of underbump metallization interconnects 109, and (ii) the plurality of inner solder interconnects 108 and/or the plurality of pillar shell interconnects 104. For example, there may be metallization interconnects between (i) the plurality of pads 107 and/or the plurality of underbump metallization interconnects 109, and (ii) the plurality of inner solder interconnects 108 and/or the plurality of pillar shell interconnects 104. Examples of metallization interconnects include redistribution interconnects. When there are metallization interconnects, the plurality of inner solder interconnects 108 and/or the plurality of pillar shell interconnects 104 may be coupled to (e.g., directly coupled to) and/or touching the metallization interconnects, instead of being directly coupled to the plurality of pads 107 and/or the plurality of underbump metallization interconnects 109.

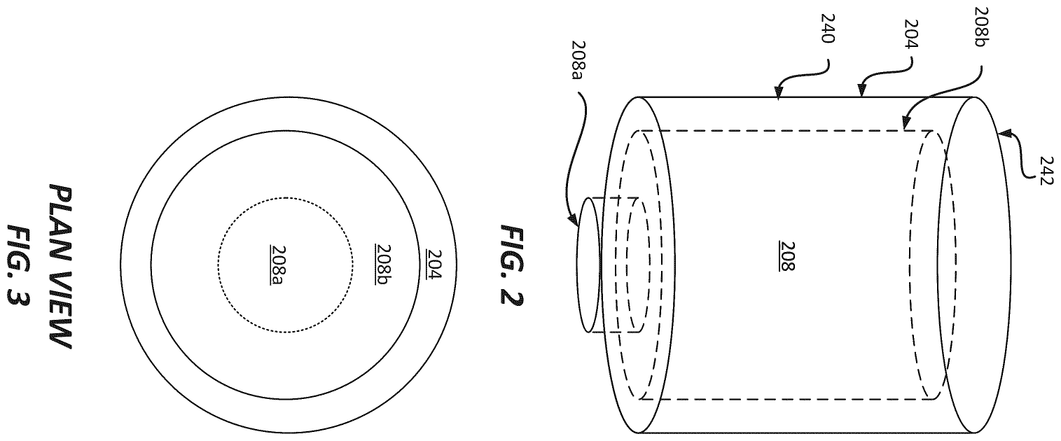

FIG. 2 illustrates an exemplary view of a pillar shell interconnect 204 and an inner solder interconnect 208. The pillar shell interconnect 204 of FIG. 2 may represent any of the pillar shell interconnects from the plurality of pillar shell interconnects from FIG. 1. The inner solder interconnect 208 of FIG. 2 may represent any of the inner solder interconnects from the plurality of inner solder interconnects from FIG. 1. As shown in FIG. 2, the pillar shell interconnect 204 may at least partially surround the inner solder interconnect 208. The pillar shell interconnect 204 may laterally surround the inner solder interconnect 208. The pillar shell interconnect 204 may have the shape of a hollow cylinder (e.g., with space inside the pillar shell interconnect 204). The space inside the pillar shell interconnect 204 may be at least partially occupied by the inner solder interconnect 208. The pillar shell interconnect 204 may include a lateral portion 240 and a top portion 242. The lateral portion 240 may include an inner lateral surface and an outer lateral surface. The top portion 242 may include an inner top surface and an outer top surface. The inner solder interconnect 208 may be touching (i) the inner lateral surface of the lateral portion 240 and (ii) the inner top surface of the top portion 242 of the pillar shell interconnect 204. A solder interconnect (e.g., from the plurality of solder interconnects 106) may touch (i) the outer top surface of the top portion 242 of the pillar shell interconnect 204 and/or (ii) the outer lateral surface of the lateral portion 240 of the pillar shell interconnect 204.

The inner solder interconnect 208 may include a first inner solder interconnect portion 208a and a second inner solder interconnect portion 208b. The first inner solder interconnect portion 208a and the second inner solder interconnect portion 208b may be continuous and/or contiguous portions of the inner solder interconnect 208. The first inner solder interconnect portion 208a includes a first diameter and/or a first width. The second inner solder interconnect portion 208b includes a second diameter and/or a second width. The second diameter and/or the second width may be greater than the first diameter and/or the first width. The first inner solder interconnect portion 208a may be configured to touch an underbump metallization interconnect from the plurality of underbump metallization interconnects 109 and/or a pad from the plurality of pads 107. The second inner solder interconnect portion 208b may be configured to touch an underbump metallization interconnect from the plurality of underbump metallization interconnects 109. The inner solder interconnect 208 may be considered to be located at least partially in the pillar shell interconnect 204, since in the example of FIG. 2, only some of the inner solder interconnect 208 are laterally surrounded by the pillar shell interconnect 204. For example, the second inner solder interconnect portion 208b is not laterally surrounded by the pillar shell interconnect 204.

FIG. 3 illustrates a cross sectional plan view of the pillar shell interconnect 204 and the inner solder interconnect 208. As shown in FIG. 3, a planar cross section that extends through the pillar shell interconnect 204 comprises an O shape. However, the planar cross section of the pillar shell interconnect 204 may have any types of shapes, including an oblong shape and/or an octagonal shape. The pillar shell interconnect 204 may have different sizes.

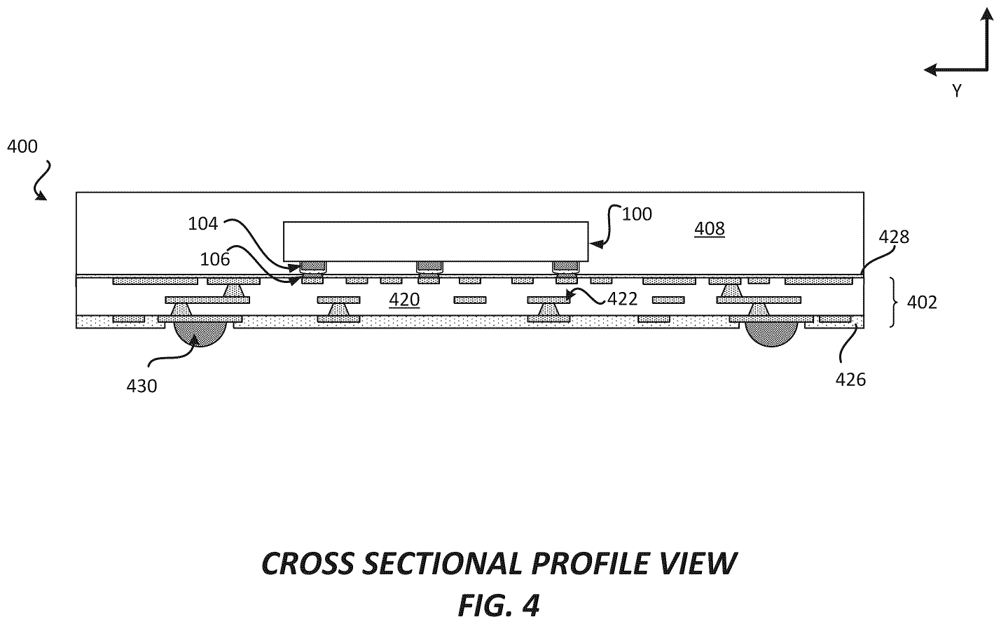

The integrated device 100 may be implemented in a package. FIG. 4 illustrates a package 400 that includes a substrate 402, the integrated device 100 and an encapsulation layer 408. The substrate 402 includes at least one dielectric layer 420, a plurality of interconnects 422, a solder resist layer 426 and a solder resist layer 428. A plurality of solder interconnects 430 may be coupled to the plurality of interconnects 422 of the substrate 402. The integrated device 100 is coupled to a first surface (e.g., top surface) of the substrate 402 through the inner solder interconnects 108, the plurality of pillar shell interconnects 104 and the plurality of solder interconnects 106. In some implementations, the inner solder interconnects 108, the plurality of pillar shell interconnects 104 and/or the plurality of solder interconnects 106 may be considered part of the integrated device. The encapsulation layer 408 may be located over and/or around the integrated device 100 and/or the substrate 402. The encapsulation layer 408 may at least partially encapsulate the integrated device 100. The encapsulation layer 408 may include a mold, a resin and/or an epoxy. The encapsulation layer 408 may be a means for encapsulation. The encapsulation layer 408 may be provided by using a compression and transfer molding process, a sheet molding process, or a liquid molding process.

FIG. 4 illustrates one integrated device coupled to the substrate. In some implementations, a package may include two or more integrated devices coupled to the substrate. One or more of the integrated devices may each include their own respective plurality of inner solder interconnects, a plurality of pillar shell interconnects and a plurality of solder interconnects.

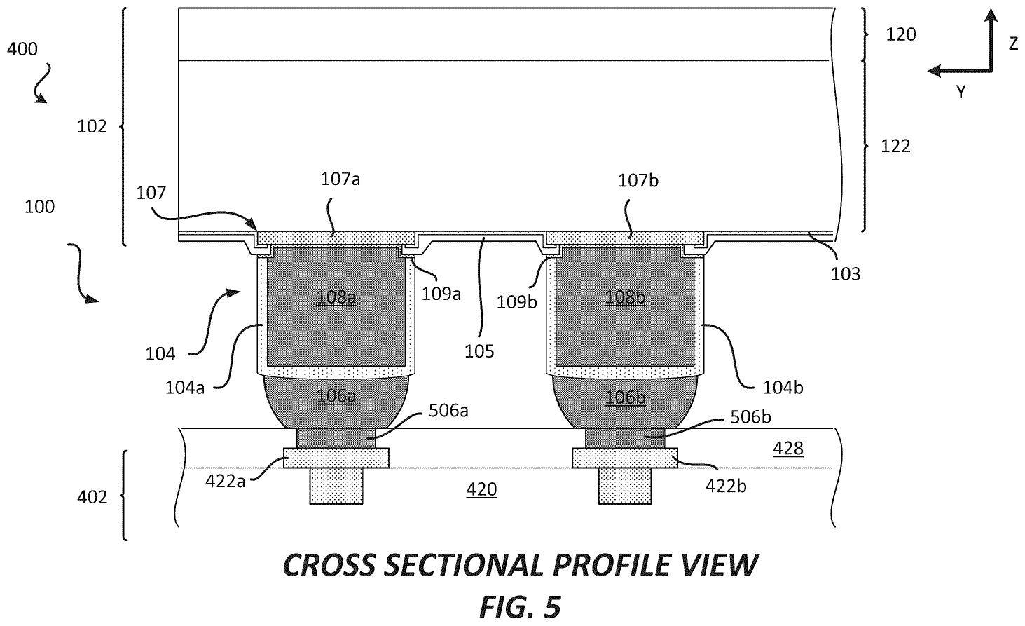

FIG. 5 illustrates an exemplary close-up view of how an integrated device may be coupled to a substrate. FIG. 5 may illustrate a portion of the package 400 that includes the integrated device 100 and the substrate 402. The integrated device 100 is coupled to the substrate 402 through the plurality of inner solder interconnects 108, the plurality of pillar shell interconnects 104, the plurality of solder interconnects 106 and the plurality of solder interconnects 506 (e.g., pre solder interconnects).

As shown in FIG. 5, the first underbump metallization interconnect 109a is coupled to the first pad 107a. The first inner solder interconnect 108a is coupled to the first underbump metallization interconnect 109a and the first pillar shell interconnect 104a. The first pillar shell interconnect 104a is coupled to the first solder interconnect 106a. The first solder interconnect 106a is coupled to a first solder interconnect 506a. The first solder interconnect 506a is coupled to a first interconnect 422a of the substrate 402. The first solder interconnect 106a and the first solder interconnect 506a may be considered to be the same solder interconnect.

The second underbump metallization interconnect 109b is coupled to the second pad 107b. The second inner solder interconnect 108b is coupled to the second underbump metallization interconnect 109b and the second pillar shell interconnect 104b. The second pillar shell interconnect 104b is coupled to the second solder interconnect 106b. The second solder interconnect 106b is coupled to a second solder interconnect 506b. The second solder interconnect 506b is coupled to a second interconnect 422b of the substrate 402. The second solder interconnect 106b and the second solder interconnect 506b may be considered to be the same solder interconnect.

An electrical path between the substrate and the transistors of the integrated device 100 may include the first interconnect 422a, the first solder interconnect 506a, the first solder interconnect 106a, the first pillar shell interconnect 104a, the first inner solder interconnect 108a, the first underbump metallization interconnect 109a, the first pad 107a, and a plurality of die interconnects from the interconnection portion 122. In the event, there may be additional interconnects between the first pad 107a and the first inner solder interconnect 108a, the electrical path may include those additional interconnects. For example, if there are additional metallization interconnects (e.g., redistribution interconnects) between the first pad 107a and the first inner solder interconnect 108a, the electrical path may include at least some of the additional metallization interconnects. It is noted that different configurations of the integrated device may bypass the use of some interconnects. As such, some interconnects of the integrated device may be optional.

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

Having described an integrated device with pillar shell interconnects and inner solder interconnects, a method for fabricating an integrated device will now be described below.

### Exemplary Sequence for Fabricating an Integrated Device Comprising a Pillar Shell Interconnect and an Inner Solder Interconnect

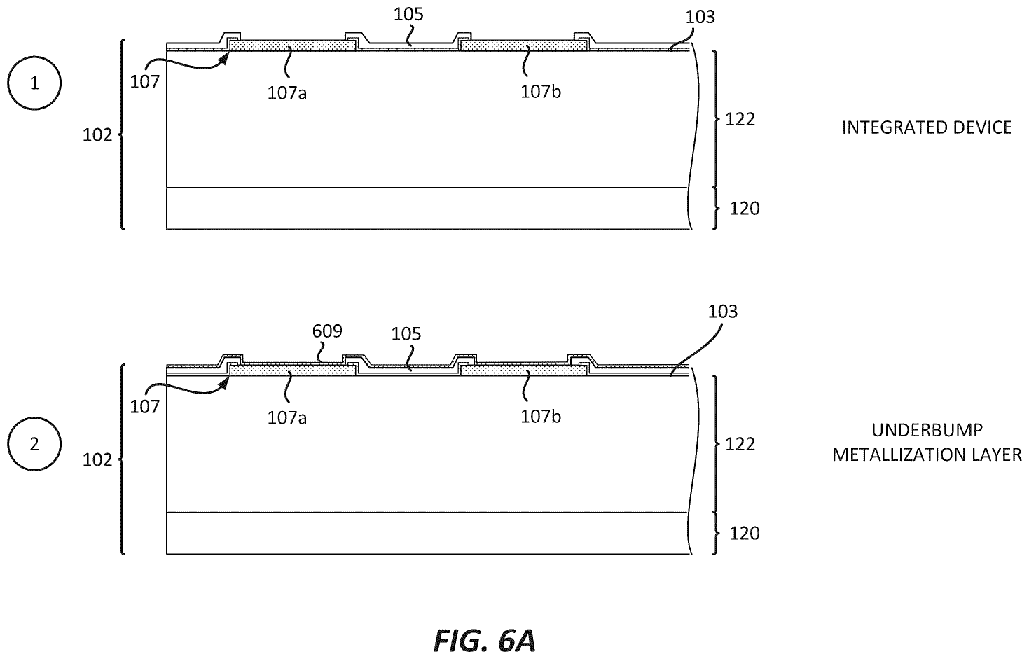

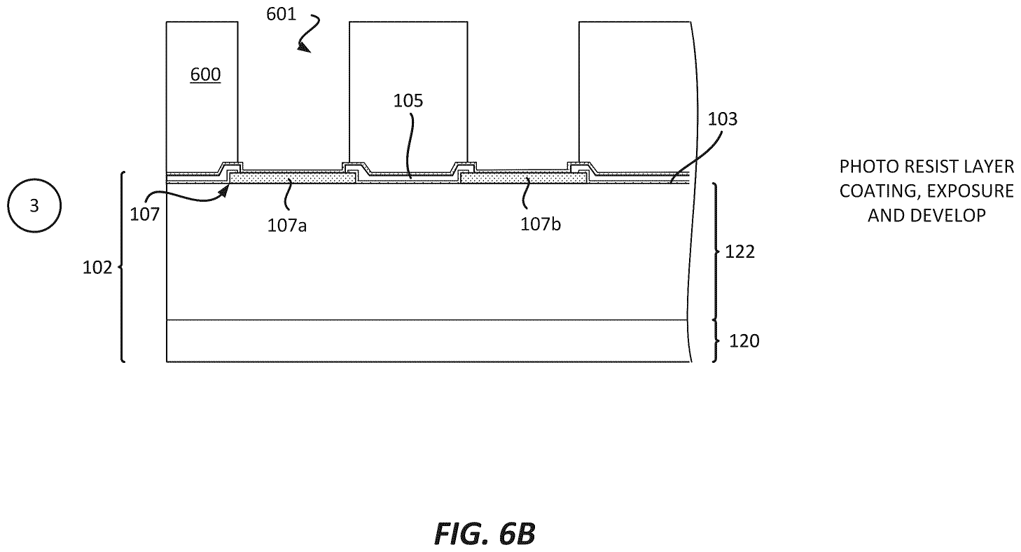

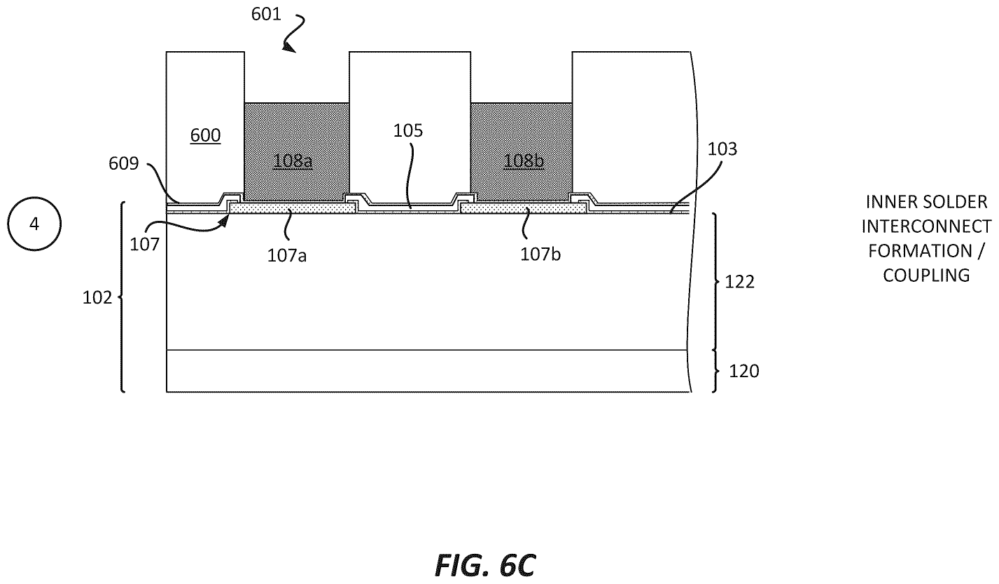

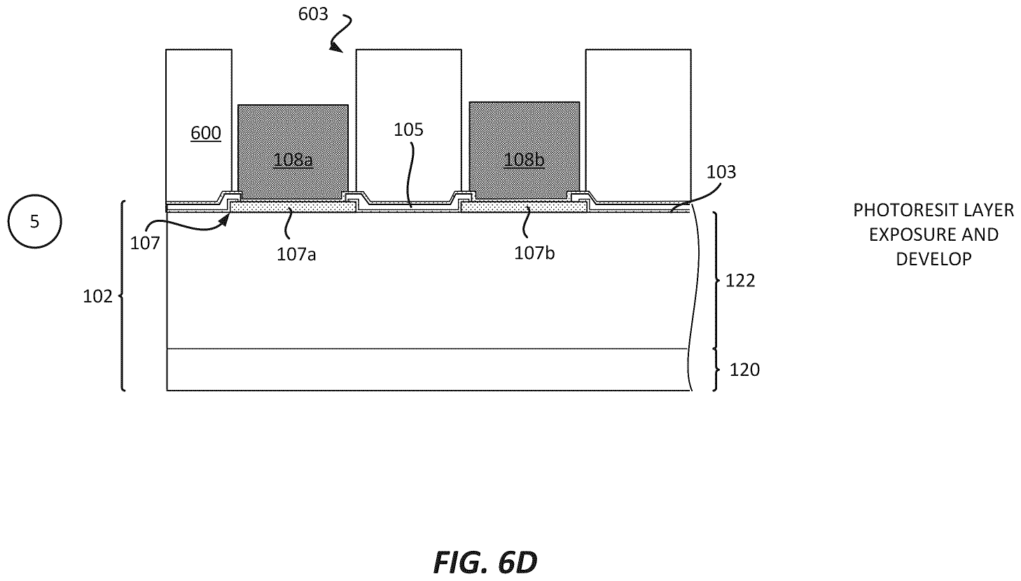

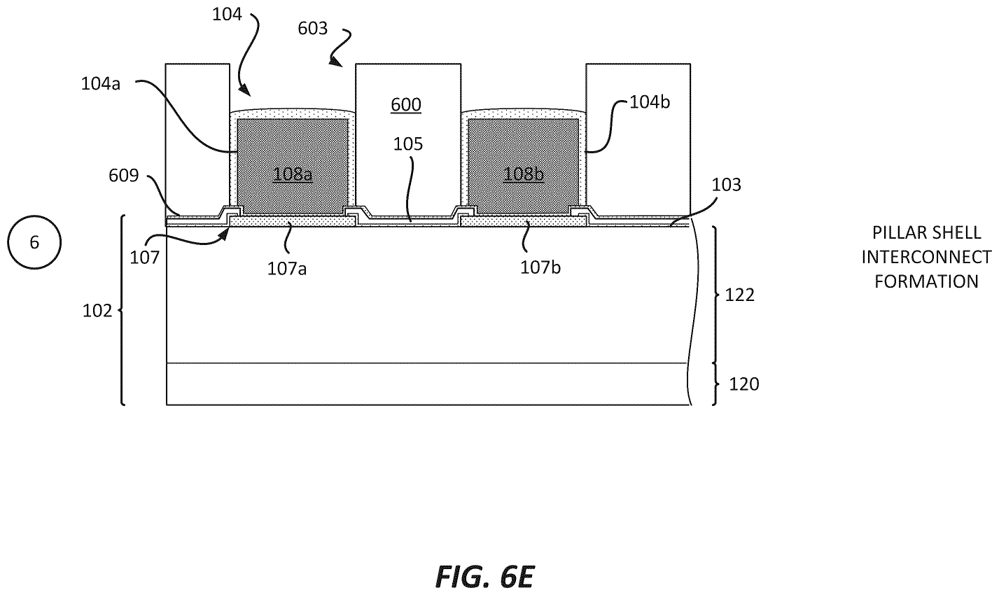

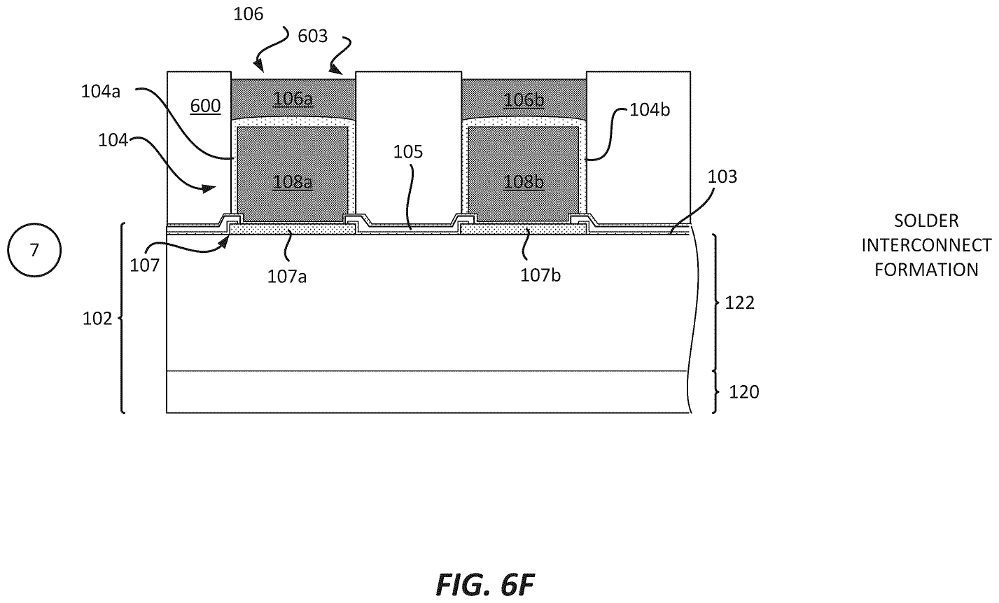

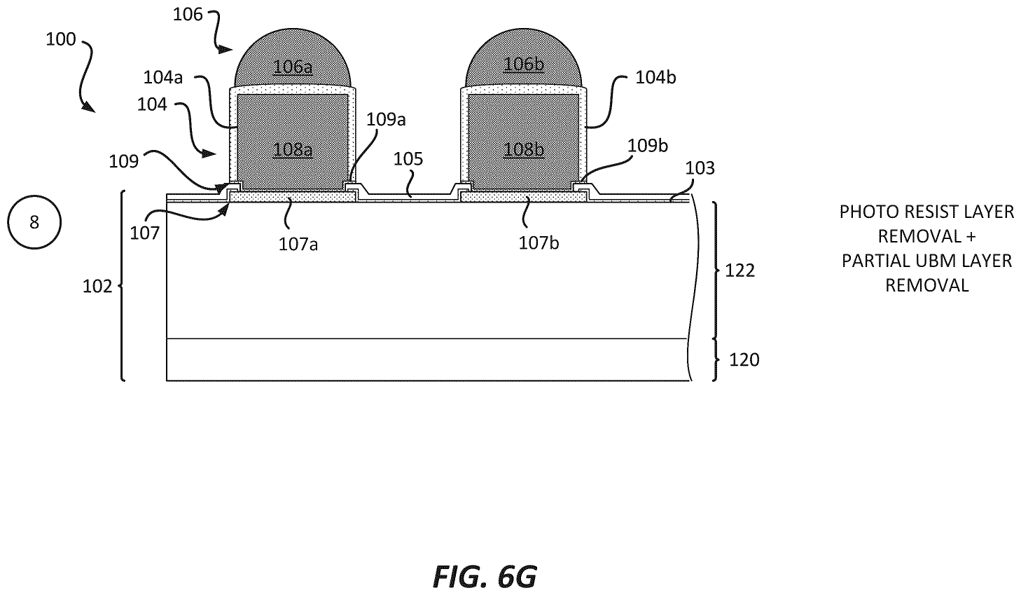

In some implementations, fabricating an integrated device includes several processes. FIGS. 6A-6G illustrate an exemplary sequence for providing or fabricating an integrated device comprising a pillar shell interconnect and an inner solder interconnect. In some implementations, the sequence of FIGS. 6A-6G may be used to provide or fabricate the integrated device 100. However, the process of FIGS. 6A-6G may be used to fabricate any of the integrated devices described in the disclosure.

It should be noted that the sequence of FIGS. 6A-6G may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 6A, illustrates a state after an integrated device is provided and/or fabricated. The integrated device 100 may include a die portion 102. The die portion 102 may include a die substrate 120, an interconnection portion 122 (e.g., die interconnection portion), a passivation layer 103, a passivation layer 105, a plurality of pads 107. The integrated device 100 may include a bare die (e.g., semiconductor bare die). Thus, in some implementations, a bare die that includes a die substrate 120, an interconnection portion 122 (e.g., die interconnection portion), at least one passivation layer (e.g., 103 and/or 105) and a plurality of pads 107, may be provided at stage 1. In some implementations, the integrated device 100 is provided and/or fabricated as part of a wafer. As will be further described below, an integrated device may include additional components and/or other components, which may be fabricated onto the integrated device that is provided at stage 1.

Stage 2 illustrates a state after an underbump metallization layer 609 is formed over the die portion 102 of the integrated device 100. The underbump metallization layer 609 may be coupled to and touch the passivation layer 105 and the plurality of pads 107. The underbump metallization layer 609 may include a different material from the plurality of pads 107. A sputtering process may be used to form the underbump metallization layer 609.

Stage 3, as shown in FIG. 6B illustrates a state after a photo resist layer 600 is formed over the die portion 102 and patterned to include a plurality of openings 601 in the photo resist layer 600. The photo resist layer 600 may be coated over the die portion 102. For example, the photo resist layer 600 may be coated over the underbump metallization layer 609. A photolithography process may be used to form and define the pattern of the photo resist layer 600. For example, an exposure process and development process may be used to form the plurality of openings 601 in the photo resist layer 600. The plurality of openings 601 may be located over the plurality of pads 107.

Stage 4, as shown in FIG. 6C illustrates a state after the plurality of inner solder interconnects 108 are formed and coupled to the plurality of pads 107 through the underbump metallization layer 609. A plating process may be used to form the plurality of inner solder interconnects 108. The plurality of inner solder interconnects 108 may touch the underbump metallization layer 609. When there is no underbump metallization layer 609, the plurality of inner solder interconnects 108 may touch the plurality of pads 107. The plurality of inner solder interconnects 108 may be formed in the plurality of openings 601 of the photo resist layer 600.

Stage 5, as shown in FIG. 6D, illustrates after the plurality of openings 601 is further opened to form a plurality of openings 603. The plurality of openings 603 may have a size that is bigger than the size of the plurality of openings 601. Another exposure process and development process may be used to form the plurality of openings 603 in the photo resist layer 600. The plurality of openings 603 may be located over the plurality of pads 107.

Stage 6, as shown in FIG. 6E, illustrates a state after the plurality of pillar shell interconnects 104 are formed. The plurality of pillar shell interconnects 104 may be formed in the plurality of openings 603 of the photo resist layer 600. The plurality of pillar shell interconnects 104 may be coupled to the plurality of inner solder interconnects 108. The plurality of pillar shell interconnects 104 may at least partially surround the plurality of inner solder interconnects 108. The plurality of pillar shell interconnects 104 may touch the plurality of inner solder interconnects 108. The plurality of pillar shell interconnects 104 may touch the underbump metallization layer 609. When there is no underbump metallization layer 609, the plurality of pillar shell interconnects 104 may touch, the passivation layer 103 and/or the passivation layer 105.

Stage 7, as shown in FIG. 6F, illustrates a state after the plurality of solder interconnects 106 are formed and coupled to the plurality of pillar shell interconnects 104. The plurality of solder interconnects 106 may be formed through the plurality of openings 603 of the photo resist layer 600. A plating process may be used to form the plurality of solder interconnects 106.

Stage 8, as shown in FIG. 6G, illustrates a state after the photo resist layer 600 is removed and a solder reflow process is performed. Stage 8 may also illustrate a state after portions of the underbump metallization layer 609 are removed to form the plurality of underbump metallization interconnects 109 that includes a first underbump metallization interconnect 109a and a second underbump metallization interconnect 109b. An etching process may be used to selectively remove portions of the underbump metallization layer 609. Stage 8 may illustrate an example of an integrated device 100 that includes a plurality of pillar shell interconnects and a plurality of inner solder interconnects.

### Exemplary Flow Diagram of a Method for Fabricating an Integrated Device Comprising a Pillar Shell Interconnect and an Inner Solder Interconnect

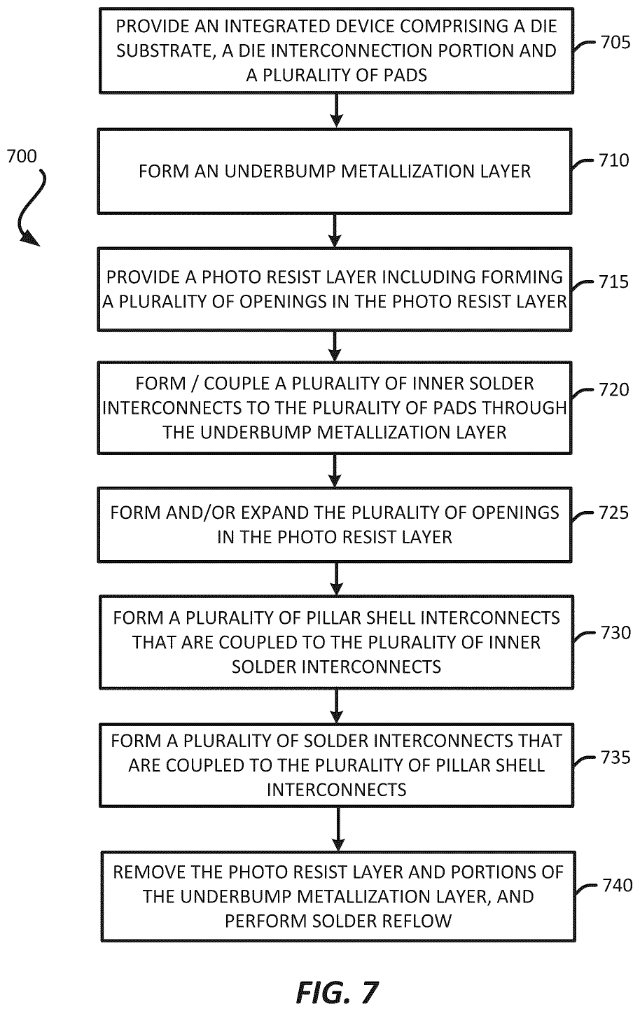

In some implementations, fabricating an integrated device includes several processes. FIG. 7 illustrates an exemplary flow diagram of a method 700 for providing or fabricating an integrated device comprising pillar shell interconnects and inner solder interconnects. In some implementations, the method 700 of FIG. 7 may be used to provide or fabricate the integrated device 100 of FIG. 1 described in the disclosure. However, the method 700 may be used to provide or fabricate any of the integrated devices described in the disclosure.

It should be noted that the method of FIG. 7 may combine one or more processes in order to simplify and/or clarify the method for providing or fabricating an integrated device. In some implementations, the order of the processes may be changed or modified.

The method provides (at 705) an integrated device that includes a die substrate, an die interconnection portion and a plurality of pads. Stage 1 of FIG. 6A, illustrates and describes an example of a state after an integrated device is provided and/or fabricated. The integrated device 100 may include a die portion 102. The die portion 102 may include a die substrate 120, an interconnection portion 122, a passivation layer 103, a passivation layer 105, a plurality of pads 107. The integrated device 100 may include a bare die (e.g., semiconductor bare die). In some implementations, the integrated device 100 is provided and/or fabricated as part of a wafer.

The method forms (at 710) an underbump metallization layer over the integrated device. Stage 2 of FIG. 6A, illustrates and describes an example of a state after an underbump metallization layer 609 is formed over the die portion 102 of the integrated device 100. The underbump metallization layer 609 may be coupled to and touch the passivation layer 105 and the plurality of pads 107. The underbump metallization layer 609 may include a different material from the plurality of pads 107. A sputtering process may be used to form the underbump metallization layer 609.

The method provides (at 715) a photo resist layer over the integrated device. Stage 3 of FIG. 6B, illustrates and describes an example of a state after a photo resist layer 600 is formed over the die portion 102 and patterned to include a plurality of openings 601 in the photo resist layer 600. The photo resist layer 600 may be coated over the die portion 102. For example, the photo resist layer 600 may be coated over the underbump metallization layer 609. A photolithography process may be used to form and define the pattern of the photo resist layer 600. For example, an exposure process and development process may be used to form the plurality of openings 601 in the photo resist layer 600. The plurality of openings 601 may be located over the plurality of pads 107.

The method forms (at 720) a plurality of inner solder interconnects coupled to the plurality of pads. Stage 4 of FIG. 6C, illustrates and describes an example of a state after the plurality of inner solder interconnects 108 are formed and coupled to the plurality of pads 107 through the underbump metallization layer 609. A plating process may be used to form the plurality of inner solder interconnects 108. The plurality of inner solder interconnects 108 may touch the underbump metallization layer 609. When there is no underbump metallization layer 609, the plurality of inner solder interconnects 108 may touch the plurality of pads 107. The plurality of inner solder interconnects 108 may be formed in the plurality of openings 601 of the photo resist layer 600.

The method forms (at 725) openings in the photo resist layer. Stage 5 of FIG. 6D, illustrates and describes an example of after the plurality of openings 601 is further opened to form plurality of openings 603. The plurality of openings 603 may have a size that is bigger than the size of the plurality of openings 601. Another exposure process and development process may be used to form the plurality of openings 603 in the photo resist layer 600. The plurality of openings 603 may be located over the plurality of pads 107.

The method forms (at 730) a plurality of pillar shell interconnects coupled to the plurality of inner solder interconnects. Stage 6 of FIG. 6E, illustrates and describes an example of a state after the plurality of pillar shell interconnects 104 are formed. The plurality of pillar shell interconnects 104 may be formed in the plurality of openings 603 of the photo resist layer 600. The plurality of pillar shell interconnects 104 may be coupled to the plurality of inner solder interconnects 108. The plurality of pillar shell interconnects 104 may at least partially surround the plurality of inner solder interconnects 108. The plurality of pillar shell interconnects 104 may touch the plurality of inner solder interconnects 108. The plurality of pillar shell interconnects 104 may touch the underbump metallization layer 609. When there is no underbump metallization layer 609, the plurality of pillar shell interconnects 104 may touch the passivation layer 103 and/or the passivation layer 105.

The method forms (at 735) a plurality of solder interconnects coupled to the plurality of pillar shell interconnects. Stage 7 of FIG. 6F, illustrates and describes an example of a state after the plurality of solder interconnects 106 are formed and coupled to the plurality of pillar shell interconnects 104. The plurality of solder interconnects 106 may be formed through the plurality of openings 603 of the photo resist layer 600. A plating process may be used to form the plurality of solder interconnects 106.

The method removes (at 740) the photo resist layer and a portion of the underbump metallization layer. Stage 8 of FIG. 6G, illustrates and describes an example of a state after the photo resist layer 600 is removed and a solder reflow process is performed. Stage 8 of FIG. 6G may also illustrate a state after portions of the underbump metallization layer 609 are removed to form the plurality of underbump metallization interconnects 109 that includes a first underbump metallization interconnect 109a and a second underbump metallization interconnect 109b. An etching process may be used to selectively remove portions of the underbump metallization layer 609.

The integrated devices (e.g., 100) described in the disclosure may be fabricated one at a time or may be fabricated together as part of one or more wafers and then singulated into individual integrated devices.

### Exemplary Sequence for Fabricating a Package Comprising an Integrated Device Comprising a Pillar Shell Interconnect and an Inner Solder Interconnect

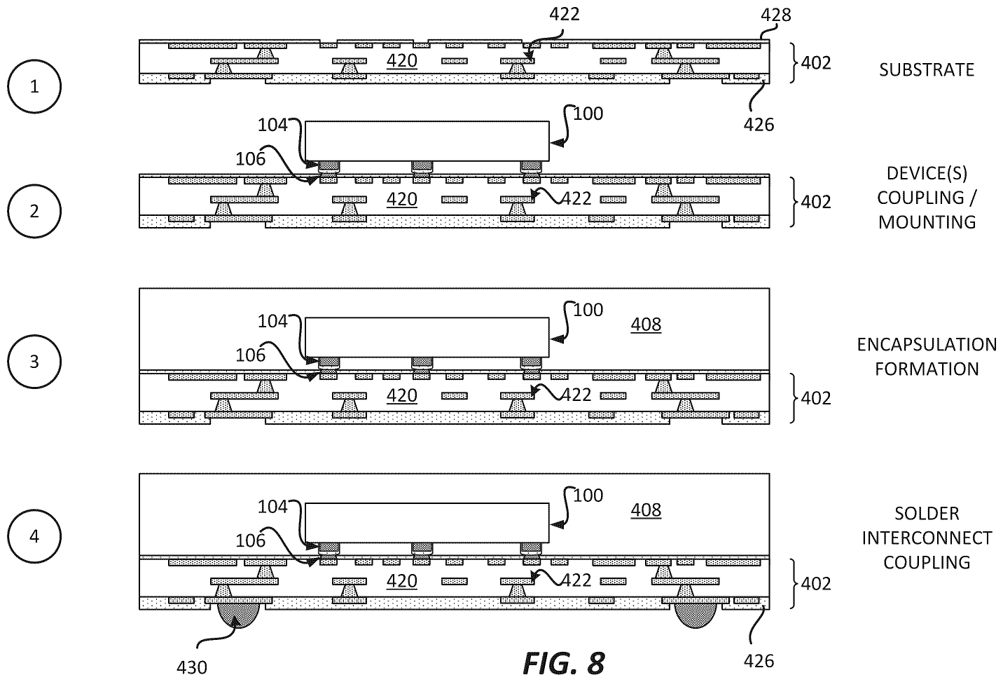

In some implementations, fabricating a package includes several processes. FIG. 8 illustrates an exemplary sequence for providing or fabricating a package that includes an integrated device comprising pillar shell interconnects and inner solder interconnects. In some implementations, the sequence of FIG. 8 may be used to provide or fabricate the package 400 of FIG. 4. However, the process of FIG. 8 may be used to fabricate any of the packages described in the disclosure.

It should be noted that the sequence of FIG. 8 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 8 illustrates a state after a substrate 402 is provided. The substrate 402 includes at least one dielectric layer 420, a plurality of interconnects 422, a solder resist layer 426 and a solder resist layer 428. Different implementations may use different substrates with different numbers of metal layers. A substrate may include a coreless substrate, a cored substrate, or an embedded trace substrate (ETS).

Stage 2 illustrates a state after the integrated device 100 is coupled to the substrate 402 through the plurality of inner solder interconnects 108, the plurality of pillar shell interconnects 104 and the plurality of solder interconnects 106. The integrated device 100 may be coupled to the plurality of interconnects 422 of the substrate 402 through the plurality of inner solder interconnects 108, the plurality of pillar shell interconnects 104 and the plurality of solder interconnects 106. A solder reflow process may be used to couple the integrated device 100 to the substrate 402. FIG. 5 illustrates an example of how the integrated device 100 may be coupled to the substrate 402. Different implementations may couple different components and/or devices to the substrate 402.

Stage 3 illustrates a state after an encapsulation layer 408 is provided (e.g., formed) over the substrate 402. The encapsulation layer 408 may encapsulate the integrated device 100. The encapsulation layer 408 may include a mold, a resin and/or an epoxy. A compression molding process, a transfer molding process, or a liquid molding process may be used to form the encapsulation layer 408. The encapsulation layer 408 may be photo etchable. The encapsulation layer 408 may be a means for encapsulation.

Stage 4 illustrates a state after a plurality of solder interconnects 430 are coupled to the substrate 402. A solder reflow process may be used to couple the plurality of solder interconnects 430 to the substrate 402.

Exemplary Flow Diagram of a Method for Fabricating a Package Comprising an Integrated Device Comprising a Pillar Shell Interconnect and an Inner Solder Interconnect

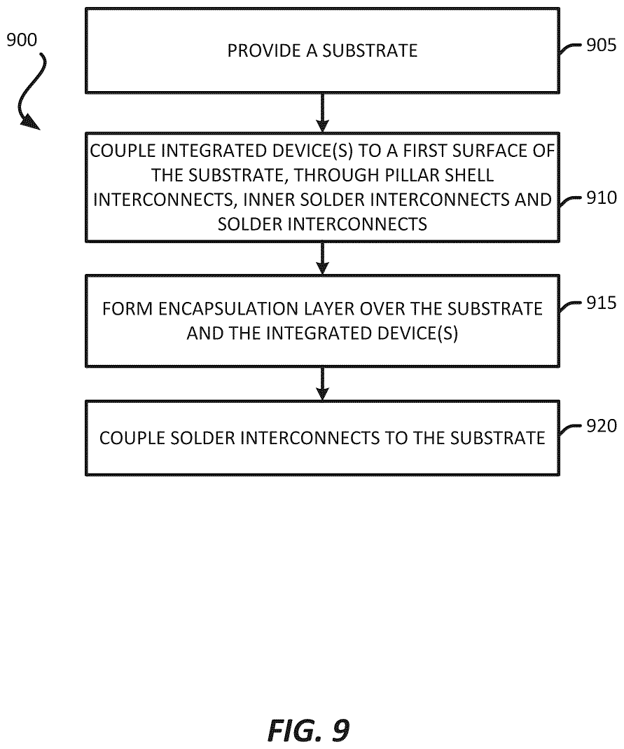

In some implementations, fabricating a package includes several processes. FIG. 9 illustrates an exemplary flow diagram of a method 900 for providing or fabricating a package comprising an integrated device that includes pillar shell interconnects an inner solder interconnects. In some implementations, the method 900 of FIG. 9 may be used to provide or fabricate the package 400 of FIG. 4 described in the disclosure. However, the method 900 may be used to provide or fabricate any of the packages (e.g., 400) described in the disclosure.

It should be noted that the method of FIG. 9 may combine one or more processes in order to simplify and/or clarify the method for providing or fabricating a package. In some implementations, the order of the processes may be changed or modified.

The method provides (at 905) a substrate (e.g., 402). The substrate 402 may be provided by a supplier or fabricated. Different implementations may use different processes to fabricate the substrate 402. Examples of processes that may be used to fabricate the substrate 402 include a semi-additive process (SAP) and a modified semi-additive process (mSAP). The substrate 402 includes at least one dielectric layer 420, a plurality of interconnects 422, a solder resist layer 426 and a solder resist layer 428. The substrate 402 may include an embedded trace substrate (ETS). In some implementations, the substrate may be a core substrate. In some implementations, the at least one dielectric layer 420 may include prepreg layers and/or polyimide. Stage 1 of FIG. 8 illustrates and describes an example of providing a substrate.

The method couples (at 910) an integrated device (e.g., 100) to a first surface of the substrate 402. For example, the integrated device 100 may be coupled to a first surface (e.g., top surface) of the substrate 402. The integrated device 100 is coupled to the substrate 402 through the plurality of inner solder interconnects 108, the plurality of pillar shell interconnects 104 and the plurality of solder interconnects 106. A solder reflow process may be used to couple the integrated device 100 to the substrate 402. FIG. 5 illustrates an example of how the integrated device 100 may be coupled to the substrate 402. Stage 2 of FIG. 8 illustrates and describes an example of coupling an integrated device to a substrate.

The method forms (at 915) an encapsulation layer (e.g., 408) over the substrate (e.g., 402). The encapsulation layer 408 may be provided and formed over and/or around the substrate 402 and the integrated device 100. The encapsulation layer 408 may include a mold, a resin and/or an epoxy. A compression molding process, a transfer molding process, or a liquid molding process may be used to form the encapsulation layer 408. The encapsulation layer 408 may be photo etchable. The encapsulation layer 408 may be a means for encapsulation. Stage 3 of FIG. 8 illustrates and describes an example of forming an encapsulation layer.

The method couples (at 920) a plurality of solder interconnects (e.g., 430) to the substrate 402. A solder reflow process may be used to couple the plurality of solder interconnects 430 to the substrate 402. Stage 4 of FIG. 8, illustrates and describes an example of coupling solder interconnects to a substrate.

The packages (e.g., 400) described in the disclosure may be fabricated one at a time or may be fabricated together as part of one or more wafers and/or panels and then singulated into individual packages.

### Exemplary Electronic Devices

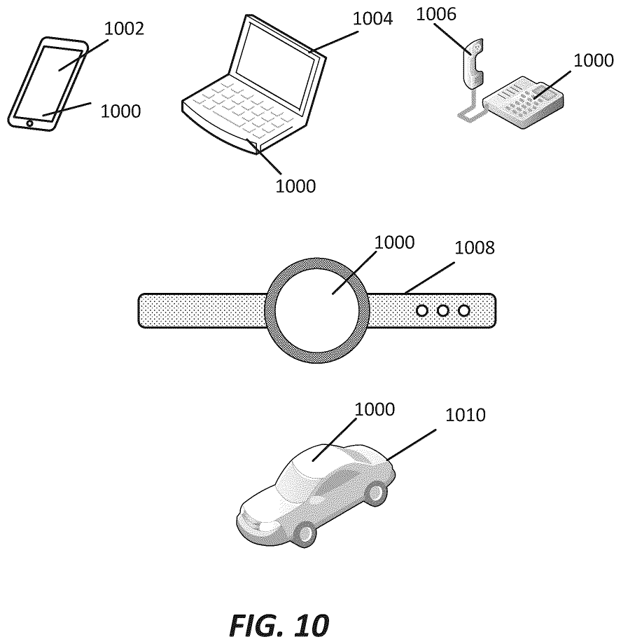

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6G, and/or 7-10 may be rearranged and/or combined into a single component, process, feature or function or embodied in several components, processes, or functions. Additional elements, components, processes, and/or functions may also be added without departing from the disclosure. It should also be noted FIGS. 1-5, 6A-6G, and/or 7-10 and its corresponding description in the present disclosure is not limited to dies and/or ICs. In some implementations, FIGS. 1-5, 6A-6G, and/or 7-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate; a plurality of pads; a plurality of inner solder interconnects coupled to the plurality of pads; and a plurality of pillar shell interconnects coupled to the plurality of inner solder interconnects, wherein the plurality of inner solder interconnects are located between the plurality of pillar shell interconnects and the plurality of pads.

Aspect 2: The integrated device of aspect 1, further comprising a plurality of underbump metallization interconnects coupled to the plurality of pads, wherein the plurality of inner solder interconnects are coupled to the plurality of pads through the plurality of underbump metallization interconnects; and a plurality of solder interconnects coupled to the plurality of pillar shell interconnects, wherein the plurality of solder interconnects are separate from the plurality of inner solder interconnects.

Aspect 3: The integrated device of aspects 1 through 2, wherein the plurality of inner solder interconnects are located at least partially inside of the plurality of pillar shell interconnects, wherein a pillar shell interconnect from the plurality of pillar shell interconnects includes a first material, and wherein an inner solder interconnect from the plurality of inner solder interconnects includes a second material that is different from the first material.

Aspect 4: The integrated device of aspects 1 through 3, wherein the plurality of pads comprise a first pad and a second pad, wherein the plurality of inner solder interconnects comprise a first inner solder interconnect and a second inner solder interconnect, and wherein the plurality of pillar shell interconnects comprise a first pillar shell interconnect and a second pillar shell interconnect.

Aspect 5: The integrated device of aspect 4, further comprising a first underbump metallization interconnect coupled to the first pad; and a second underbump metallization interconnect coupled to the second pad, wherein the first inner solder interconnect is coupled to and touching the first underbump metallization interconnect and the first pillar shell interconnect, and wherein the second inner solder interconnect is coupled to and touching the second underbump metallization interconnect and the second pillar shell interconnect.

Aspect 6: The integrated device of aspects 4 through 5, wherein the first inner solder interconnect is located between the first pad and the first pillar shell interconnect, and wherein the second inner solder interconnect is located between the second pad and the second pillar shell interconnect.

Aspect 7: The integrated device of aspects 4 through 6, wherein the first pillar shell interconnect and the second pillar shell interconnect are touching a passivation layer of the integrated device.

Aspect 8: The integrated device of aspects 4 through 7, further comprising a first solder interconnect, wherein the first pillar shell interconnect includes a first lateral portion and a first top portion, wherein the first top portion comprises a first outer top surface and a first inner top surface, wherein the first inner solder interconnect touches the first inner top surface, and wherein the first solder interconnect touches the first outer top surface.

Aspect 9: The integrated device of aspects 1 through 8, further comprising a die interconnection portion coupled to the die substrate, wherein the plurality of pads are coupled to the die interconnection portion.

Aspect 10: The integrated device of aspects 1 through 9, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 11: A package comprising a substrate; and an integrated device coupled to the substrate through at least a plurality of solder interconnects, wherein the integrated device comprises: a die substrate; a plurality of pads; a plurality of inner solder interconnects coupled to the plurality of pads; and a plurality of pillar shell interconnects coupled to the plurality of inner solder interconnects, wherein the plurality of inner solder interconnects are located between the plurality of pillar shell interconnects and the plurality of pads, and wherein the plurality of solder interconnects are coupled to the plurality of pillar shell interconnects.

Aspect 12: The package of aspect 11, wherein the integrated device further comprises a plurality of underbump metallization interconnects coupled to the plurality of pads, wherein the plurality of inner solder interconnects are coupled to the plurality of pads through the plurality of underbump metallization interconnects, and wherein the plurality of solder interconnects are separate from the plurality of inner solder interconnects.

Aspect 13: The package of aspects 11 through 12, wherein the plurality of inner solder interconnects are located at least partially inside of the plurality of pillar shell interconnects, wherein a pillar shell interconnect from the plurality of pillar shell interconnects includes a first material, and wherein an inner solder interconnect from the plurality of inner solder interconnects includes a second material that is different from the first material.

Aspect 14: The package of aspects 11 through 13, wherein the plurality of pads comprise a first pad and a second pad, wherein the plurality of inner solder interconnects comprise a first inner solder interconnect and a second inner solder interconnect, and wherein the plurality of pillar shell interconnects comprise a first pillar shell interconnect and a second pillar shell interconnect.

Aspect 15: The package of aspect 14, further comprising: a first underbump metallization interconnect coupled to the first pad; and a second underbump metallization interconnect coupled to the second pad, wherein the first inner solder interconnect is coupled to and touching the first underbump metallization interconnect and the first pillar shell interconnect, and wherein the second inner solder interconnect is coupled to and touching the second underbump metallization interconnect and the second pillar shell interconnect.

Aspect 16: The package of aspects 14 through 15, wherein the first inner solder interconnect is located between the first pad and the first pillar shell interconnect, and wherein the second inner solder interconnect is located between the second pad and the second pillar shell interconnect.

Aspect 17: The package of aspects 14 through 16, wherein the first pillar shell interconnect and the second pillar shell interconnect are touching a passivation layer of the integrated device.

Aspect 18: The package of aspects 14 through 17, further comprising a first solder interconnect, wherein the first pillar shell interconnect includes a first lateral portion and a first top portion, wherein the first top portion comprises a first outer top surface and a first inner top surface, wherein the first inner solder interconnect touches the first inner top surface, and wherein the first solder interconnect touches the first outer top surface.

Aspect 19: The package of aspects 11 through 18, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 20: A method for fabricating an integrated device. The method provides an integrated device comprising a die substrate and a plurality of pads. The method couples a plurality of inner solder interconnects to the plurality of pads. The method forms a plurality of pillar shell interconnects that are coupled to the plurality of inner solder interconnects such that the plurality of inner solder interconnects are located between the plurality of pillar shell interconnects and the plurality of pads.

Aspect 21: The method of aspect 20, further comprising coupling a plurality of solder interconnects to the plurality of pillar shell interconnects.

Aspect 22: The method of aspect 21, wherein the plurality of solder interconnects and the plurality of inner solder interconnects are separate, and wherein the integrated device further comprises a plurality of underbump metallization interconnects coupled to the plurality of pads, wherein the plurality of inner solder interconnects are coupled to the plurality of pads through the plurality of underbump metallization interconnects.

Aspect 23: The method of aspects 20 through 22, wherein the plurality of inner solder interconnects are located at least partially inside of the plurality of pillar shell interconnects.

Aspect 24: The method of aspects 20 through 23, wherein the plurality of pads comprise a first pad and a second pad, wherein the plurality of inner solder interconnects comprise a first inner solder interconnect and a second inner solder interconnect, and wherein the plurality of pillar shell interconnects comprise a first pillar shell interconnect and a second pillar interconnect.

Aspect 25: The method of aspect 24, further comprising forming a first underbump metallization interconnect coupled to the first pad; and forming a second underbump metallization interconnect coupled to the second pad, wherein the first inner solder interconnect is coupled to and touching the first underbump metallization interconnect and the first pillar shell interconnect, and wherein the second inner solder interconnect is coupled to and touching the second underbump metallization interconnect and the second pillar shell interconnect.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate;
a plurality of pads;
a plurality of inner solder interconnects coupled to the plurality of pads; and
a plurality of pillar shell interconnects coupled to the plurality of inner solder interconnects,
wherein the plurality of inner solder interconnects are located between the plurality of pillar shell interconnects and the plurality of pads.

2. The integrated device of claim 1, further comprising:
a plurality of underbump metallization interconnects coupled to the plurality of pads, wherein the plurality of inner solder interconnects are coupled to the plurality of pads through the plurality of underbump metallization interconnects; and
a plurality of solder interconnects coupled to the plurality of pillar shell interconnects, wherein the plurality of solder interconnects are separate from the plurality of inner solder interconnects.

3. The integrated device of claim 1,
wherein the plurality of inner solder interconnects are located at least partially inside of the plurality of pillar shell interconnects,
wherein a pillar shell interconnect from the plurality of pillar shell interconnects includes a first material, and
wherein an inner solder interconnect from the plurality of inner solder interconnects includes a second material that is different from the first material.

4. The integrated device of claim 1,
wherein the plurality of pads comprise a first pad and a second pad,
wherein the plurality of inner solder interconnects comprise a first inner solder interconnect and a second inner solder interconnect, and
wherein the plurality of pillar shell interconnects comprise a first pillar shell interconnect and a second pillar shell interconnect.

5. The integrated device of claim 4, further comprising:
a first underbump metallization interconnect coupled to the first pad; and
a second underbump metallization interconnect coupled to the second pad,
wherein the first inner solder interconnect is coupled to and touching the first underbump metallization interconnect and the first pillar shell interconnect, and
wherein the second inner solder interconnect is coupled to and touching the second underbump metallization interconnect and the second pillar shell interconnect.

6. The integrated device of claim 4,
wherein the first inner solder interconnect is located between the first pad and the first pillar shell interconnect, and
wherein the second inner solder interconnect is located between the second pad and the second pillar shell interconnect.

7. The integrated device of claim 4, wherein the first pillar shell interconnect and the second pillar shell interconnect are touching a passivation layer of the integrated device.

8. The integrated device of claim 4, further comprising a first solder interconnect,
wherein the first pillar shell interconnect includes a first lateral portion and a first top portion,
wherein the first top portion comprises a first outer top surface and a first inner top surface,
wherein the first inner solder interconnect touches the first inner top surface, and
wherein the first solder interconnect touches the first outer top surface.

9. The integrated device of claim 1, further comprising a die interconnection portion coupled to the die substrate, wherein the plurality of pads are coupled to the die interconnection portion.

10. The integrated device of claim 1, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A package comprising:
a substrate; and
an integrated device coupled to the substrate through at least a plurality of solder interconnects, wherein the integrated device comprises:
a die substrate;
a plurality of pads;
a plurality of inner solder interconnects coupled to the plurality of pads; and
a plurality of pillar shell interconnects coupled to the plurality of inner solder interconnects,
wherein the plurality of inner solder interconnects are located between the plurality of pillar shell interconnects and the plurality of pads, and
wherein the plurality of solder interconnects are coupled to the plurality of pillar shell interconnects.

12. The package of claim 11,
wherein the integrated device further comprises a plurality of underbump metallization interconnects coupled to the plurality of pads,
wherein the plurality of inner solder interconnects are coupled to the plurality of pads through the plurality of underbump metallization interconnects, and
wherein the plurality of solder interconnects are separate from the plurality of inner solder interconnects.

13. The package of claim 11,
wherein the plurality of inner solder interconnects are located at least partially inside of the plurality of pillar shell interconnects,
wherein a pillar shell interconnect from the plurality of pillar shell interconnects includes a first material, and
wherein an inner solder interconnect from the plurality of inner solder interconnects includes a second material that is different from the first material.

14. The package of claim 11,
wherein the plurality of pads comprise a first pad and a second pad,
wherein the plurality of inner solder interconnects comprise a first inner solder interconnect and a second inner solder interconnect, and
wherein the plurality of pillar shell interconnects comprise a first pillar shell interconnect and a second pillar shell interconnect.

15. The package of claim 14, further comprising:
a first underbump metallization interconnect coupled to the first pad; and
a second underbump metallization interconnect coupled to the second pad,
wherein the first inner solder interconnect is coupled to and touching the first underbump metallization interconnect and the first pillar shell interconnect, and
wherein the second inner solder interconnect is coupled to and touching the second underbump metallization interconnect and the second pillar shell interconnect.

16. The package of claim 14,
wherein the first inner solder interconnect is located between the first pad and the first pillar shell interconnect, and
wherein the second inner solder interconnect is located between the second pad and the second pillar shell interconnect.

17. The package of claim 14, wherein the first pillar shell interconnect and the second pillar shell interconnect are touching a passivation layer of the integrated device.

18. The package of claim 14, further comprising a first solder interconnect,
wherein the first pillar shell interconnect includes a first lateral portion and a first top portion,
wherein the first top portion comprises a first outer top surface and a first inner top surface,
wherein the first inner solder interconnect touches the first inner top surface, and
wherein the first solder interconnect touches the first outer top surface.

19. The package of claim 11, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

20. A method comprising:
providing an integrated device comprising a die substrate and a plurality of pads;
coupling a plurality of inner solder interconnects to the plurality of pads; and
forming a plurality of pillar shell interconnects that are coupled to the plurality of inner solder interconnects such that the plurality of inner solder interconnects are located between the plurality of pillar shell interconnects and the plurality of pads.

21. The method of claim 20, further comprising coupling a plurality of solder interconnects to the plurality of pillar shell interconnects.

22. The method of claim 21,
wherein the plurality of solder interconnects and the plurality of inner solder interconnects are separate, and
wherein the integrated device further comprises a plurality of underbump metallization interconnects coupled to the plurality of pads, wherein the plurality of inner solder interconnects are coupled to the plurality of pads through the plurality of underbump metallization interconnects.

23. The method of claim 20, wherein the plurality of inner solder interconnects are located at least partially inside of the plurality of pillar shell interconnects.

24. The method of claim 20,
wherein the plurality of pads comprise a first pad and a second pad,
wherein the plurality of inner solder interconnects comprise a first inner solder interconnect and a second inner solder interconnect, and
wherein the plurality of pillar shell interconnects comprise a first pillar shell interconnect and a second pillar shell interconnect.

25. The method of claim 24, further comprising:
forming a first underbump metallization interconnect coupled to the first pad; and
forming a second underbump metallization interconnect coupled to the second pad,
wherein the first inner solder interconnect is coupled to and touching the first underbump metallization interconnect and the first pillar shell interconnect, and
wherein the second inner solder interconnect is coupled to and touching the second underbump metallization interconnect and the second pillar shell interconnect.
